(19) United States
(12) Patent Application Publication
(10) Pub. No.: US 2020/0203562 A1
(43) Pub. Date: Jun. 25, 2020

(54) SEMICONDUCTOR LIGHT EMITTING ELEMENT AND METHOD OF MANUFACTURING THE SAME

(71) Applicant: STANLEY ELECTRIC CO., LTD., Tokyo (JP)

(72) Inventors: Yasuyuki SHIBATA, Tokyo (JP); Hiroyuki TOGAWA, Tokyo (JP)

(73) Assignee: STANLEY ELECTRIC CO., LTD., Tokyo (JP)

(21) Appl. No.: 16/717,903

(22) Filed: Dec. 17, 2019

(30) Foreign Application Priority Data
Dec. 20, 2018 (JP) 2018-238695

(51) Int. Cl. H01L 33/06; H01L 33/30; H01L 33/00

(52) U.S. Cl. CPC H01L 33/06; H01L 33/0062; H01L 33/30

(57) ABSTRACT

A semiconductor light emitting element includes a structure in which a first clad layer having a first conductivity type, an active layer in which a quantum well layer is enclosed between barrier layers, and a second clad layer having a second conductivity type opposite to the first conductivity type are sequentially laminated on at least a substrate, wherein the quantum well layer is constituted by an In-based compound semiconductor that does not contain Al, and the active layer contains a higher concentration of Al than at least the barrier layer in an interface between the quantum well layer and the barrier layer where changing from the quantum well layer to the barrier layer when seen from a side of the substrate.

### CROSS-REFERENCE TO RELATED APPLICATION

Priority is claimed on Japanese Patent Application No. 2018-238695, filed Dec. 20, 2018, the content of which is incorporated herein by reference.

### BACKGROUND

### Field of the Invention

The present invention relates to a semiconductor light emitting element and a method of manufacturing the same.

### Description of Related Art

For example, there are semiconductor light emitting elements such as a light emitting diode (LED), a laser diode (LD), or the like. A semiconductor light emitting element including a double heterostructure obtained by sequentially laminating an n-type clad layer, an active layer (a light emitting layer) and a p-type clad layer on a substrate through epitaxial growth has become mainstream.

In addition, in epitaxial growth of each layer, metal organic chemical vapor deposition (MOCVD) is used. MOCVD is a type of vapor phase epitaxy (VPE) of growing a metal component in a source gas on a substrate through crystal growth using a thermal decomposition reaction of an organic metal material gas that is the source gas.

Further, in a semiconductor light emitting element, a quantum well structure formed by enclosing an extremely thin layer (referred to as “a quantum well layer”) having a small band gap with a layer (referred to as “a barrier layer”) having a large band gap using the above-mentioned MOCVD is used as an active layer (for example, see Japanese Translation of PCT International Application Publication No. JP 2009-545865).

In the quantum well structure, since a carrier (electrons and holes) can be confined in the quantum well layer, luminous efficiency can be increased. Further, a structure obtained by alternately laminating pluralities of barrier layers and quantum well layers in between a barrier layer disposed as the lowermost layer and a barrier layer disposed as the uppermost layer is referred to as a multi quantum well (MQW) structure.

### SUMMARY

Incidentally, in a semiconductor light emitting element using the quantum well structure in the active layer, when an effect of confining a carrier to the above-mentioned quantum well layer is enhanced as a change in composition in an interface between the barrier layer and the quantum well layer can be made sharper, improvement in luminous efficiency can be expected.

Meanwhile, in a method of manufacturing a semiconductor light emitting element, formation of the active layer having the above-mentioned quantum well structure is performed while alternately switching between a process of forming a barrier layer using a source gas for the barrier layer through epitaxial growth and a process of forming a quantum well layer using a source gas for the quantum well layer through epitaxial growth.

However, in a method of forming such an active layer, it is considered that making a change in composition in the interface between the barrier layer and the quantum well layer sharper is a problem. For example, when the active layer is formed using InGaAs having a larger lattice constant than that of GaAs on a quantum well layer and using GaAsP having a smaller lattice constant than that of GaAs on a barrier layer, the change in composition in the interface between the barrier layer and the quantum well layer is gradual.

In the active layer, a balance of distortion due to a difference in lattice constant with respect to a substrate is adjusted by alternately laminating a quantum well layer formed of InGaAs having a larger lattice constant than that of GaAs and a barrier layer formed of GaAsP having a smaller lattice constant than that of GaAs on a substrate formed of GaAs.

In the case in which the change in composition in the interface between the barrier layer and the quantum well layer is not sharp, when the above-mentioned balance of distortion tends to collapse and is biased to either one, it is thought that transition due to distortion will occur, leading to a decrease in output.

An aspect of the present invention provides a semiconductor light emitting element capable of further improving luminous efficiency, and a method of manufacturing the same.

In order to accomplish the above-mentioned purposes, the present invention provides the following means.

[1] A semiconductor light emitting element including a structure in which a first clad layer having a first conductivity type, an active layer in which a quantum well layer is enclosed between barrier layers, and a second clad layer having a second conductivity type opposite to the first conductivity type are sequentially laminated on at least a substrate,

wherein the quantum well layer is constituted by an In-based compound semiconductor that does not contain Al, and

the active layer contains a higher concentration of Al of Al than at least the barrier layer in an interface between the quantum well layer and the barrier layer where changing from the quantum well layer to the barrier layer when seen from a side of the substrate.

[2] The semiconductor light emitting element according to the above-mentioned [1], wherein the quantum well layer is constituted by an InGaAs-based compound semiconductor that does not contain Al.

[3] The semiconductor light emitting element according to the above-mentioned [1] or [2], wherein the active layer contains a higher concentration of Al than at least the barrier layer in the interface between the barrier layer and the quantum well layer where changing from the barrier layer to the quantum well layer when seen from the side of the substrate.

[4] The semiconductor light emitting element according to the above-mentioned [3], wherein the barrier layer is constituted by a GaAsP-based compound semiconductor that does not contain Al, or an AlGaAsP-based compound semiconductor having a lower concentration of Al than in the interface between the barrier layer and the quantum well layer.

[5] The semiconductor light emitting element according to the above-mentioned [3] or [4], wherein, when seen from the side of the substrate, the active layer has a first intermediate layer that contains a higher concentration of Al than at least the barrier layer and that is disposed between the quantum well layer and the barrier layer where changing from the quantum well layer to the barrier layer, and a second intermediate layer that contains a higher concentration of Al than at least the barrier layer and that is disposed between the barrier layer and the quantum well layer where changing from the barrier layer to the quantum well layer, and

the first intermediate layer has a higher concentration of In than the second intermediate layer.

[6] The semiconductor light emitting element according to any one of the above-mentioned [1] to [5], wherein, when seen from the side of the substrate, the active layer has a multi quantum well structure in which the barrier layer and the quantum well layer are alternately laminated in between the barrier layer disposed as the lowermost layer and the barrier layer disposed as the uppermost layer.

[7] A method of manufacturing a semiconductor light emitting element including a structure in which a first clad layer having a first conductivity type, an active layer in which a quantum well layer is enclosed between barrier layers, and a second clad layer having a second conductivity type opposite to the first conductivity type are sequentially laminated on at least a substrate,

the method including:

forming the active layer in which the quantum well layer is enclosed between the barrier layers while alternately switching between a process of forming the barrier layer through epitaxial growth using a source gas for the barrier layer and a process of forming the quantum well layer through epitaxial growth using a source gas for the quantum well layer,

performing crystal growth of an In-based compound semiconductor that does not contain Al in the process of forming the quantum well layer; and

performing crystal growth of Al through epitaxial growth using a source gas containing Al between the switching from the process of forming the quantum well layer to the process of forming the barrier layer.

[8] The method of manufacturing the semiconductor light emitting element according to the above-mentioned [7], wherein crystal growth of an InGaAs-based compound semiconductor that does not contain Al is performed in the process of forming the quantum well layer.

[9] The method of manufacturing the semiconductor light emitting element according to the above-mentioned [7] or [8], wherein crystal growth of Al is performed through epitaxial growth using a source gas containing Al between the switching from the process of forming the barrier layer to the process of forming the quantum well layer.

[10] The method of manufacturing the semiconductor light emitting element according to the above-mentioned [9], wherein crystal growth of a GaAsP-based compound semiconductor that does not contain Al or an AlGaAsP-based compound semiconductor having a lower concentration of Al than that in an interface between the barrier layer and the quantum well layer is performed in the process of forming the barrier layer.

[11] The method of manufacturing the semiconductor light emitting element according to any one of the above-mentioned [7] to [10], wherein trimethylaluminum (TMA) is used as the source gas containing Al.

[12] The method of manufacturing the semiconductor light emitting element according to any one of the above-mentioned [7] to [11], wherein, when seen from the side of the substrate, the active layer that has a multi quantum well structure in which pluralities of the barrier layers and the quantum well layers are alternately laminated in between the barrier layer disposed as the lowermost layer and the barrier layer disposed as the uppermost layer is formed.

As described above, according to the aspect of the present invention, it is possible to provide a semiconductor light emitting element capable of further improving luminous efficiency, and a method of manufacturing the same.

### BRIEF DESCRIPTION OF THE DRAWINGS

FIG. 1 is a cross-sectional view showing a configuration of a semiconductor light emitting element according to a first embodiment of the present invention.

FIG. 2 is a schematic cross-sectional view showing a configuration of an epitaxial growth layer provided in the semiconductor light emitting element shown in FIG. 1.

FIG. 3 is a schematic cross-sectional view showing a configuration of an active layer provided in the epitaxial growth layer shown in FIG. 2.

FIG. 4 is a sequence diagram showing a procedure of switching supply of source gases when the active layer shown in FIG. 3 is formed.

FIG. 5 is a schematic cross-sectional view showing a configuration of an active layer provided in a semiconductor light emitting element according to a second embodiment of the present invention.

FIG. 6 is a sequence diagram showing a procedure of switching supply of source gas when the active layer shown in FIG. 5 is formed.

FIG. 7 is a schematic cross-sectional view showing a configuration of an active layer provided in a semiconductor light emitting element according to a third embodiment of the present invention.

FIG. 8 is a sequence diagram showing a procedure of switching supply of source gas when the active layer shown in FIG. 7 is formed.

FIG. 9 is a schematic cross-sectional view showing a configuration of a substrate and an epitaxial growth layer provided in a semiconductor light emitting element of Example 1.

FIG. 10 is a sequence diagram showing a procedure of switching supply of source gases when layers that form the epitaxial growth layer shown in FIG. 9 are formed.

FIG. 11 is a schematic cross-sectional view showing a configuration of a sample of Example 2.

FIG. 12 is a graph showing measurement results of SIMS analysis of the sample shown in FIG. 11.

FIG. 13 is a graph showing results obtained by measuring changes in composition of In in the sample shown in FIG. 11.

FIG. 14 is an enlarged graph of a part of the graph shown in FIG. 13.

FIG. 15 is a schematic view showing energy levels of layers that constitute an active layer of the sample shown in FIG. 11.

### DETAILED DESCRIPTION OF THE INVENTION

Hereinafter, embodiments of the present invention will be described in detail with reference to the accompanying drawings.

Further, in the drawings used in the following description, in order to make components easier to see, dimensional scales may be different depending on the components, and dimensional ratios or the like in the components may not always be the same as the actual ones. In addition, materials or the like exemplified in the following description are examples, and the present invention is not particularly limited thereto and may be appropriately modified without departing from the scope of the present invention.

### First Embodiment

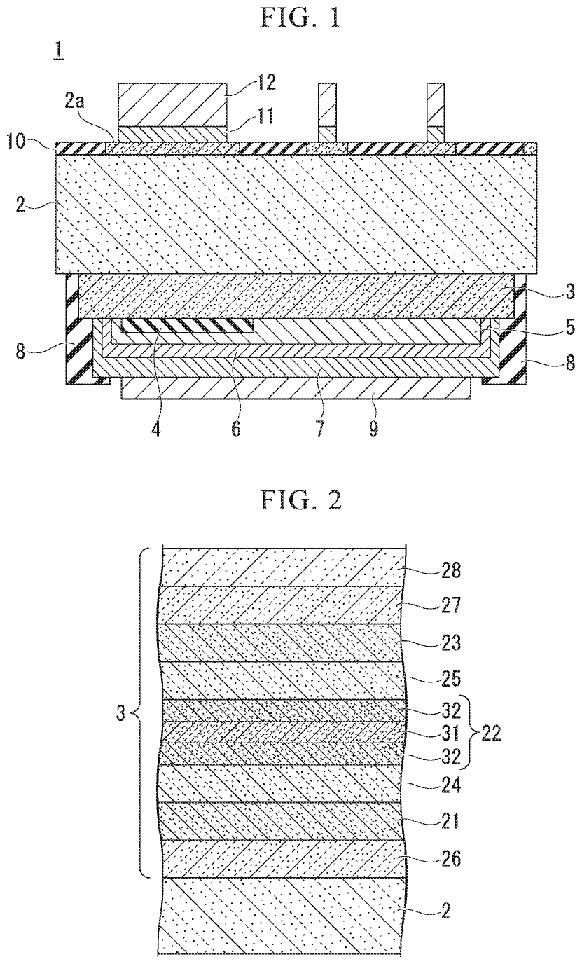

First, for example, a semiconductor light emitting element 1 shown in FIG. 1 to FIG. 3 will be described as a first embodiment of the present invention.

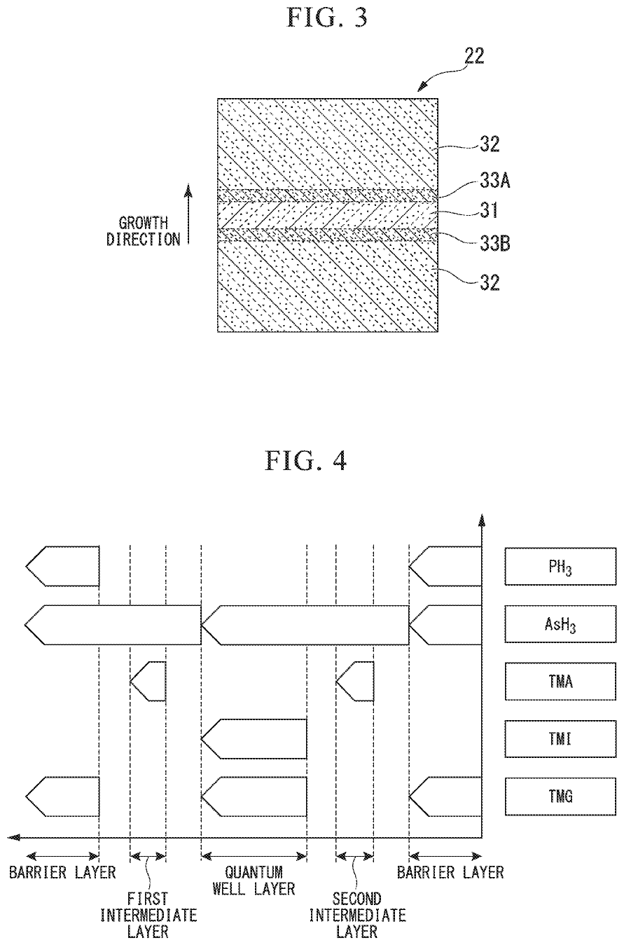

Further, FIG. 1 is a cross-sectional view showing a configuration of the semiconductor light emitting element 1. FIG. 2 is a cross-sectional view showing a lamination structure of an epitaxial growth layer 3 provided in the semiconductor light emitting element 1. FIG. 3 is a cross-sectional view showing a configuration of an active layer 22 provided in the epitaxial growth layer 3.

The semiconductor light emitting element 1 of the embodiment is obtained by, for example, applying the present invention to a light emitting diode (LED) configured to emit infrared light (for example, infrared light having a peak wavelength of 940 nm). Further, the peak wavelength of the infrared light preferably has a range of 780 nm to 1 μm, and more preferably has a range of 880 nm to 940 nm.

Specifically, as shown in FIG. 1, the semiconductor light emitting element 1 has the epitaxial growth layer 3, an insulating layer 4, a p-side contact electrode 5, a reflecting layer 6, a first protective layer 7, a second protective layer 8 and a third protective layer 9 on one surface (a lower surface in FIG. 1) of a substrate 2.

The substrate 2 is constituted by a semiconductor substrate having a first conductivity type (an n type in the embodiment). The epitaxial growth layer 3 is provided on a surface of the substrate 2 through epitaxial growth, which will be described below. The insulating layer 4 is provided to partially cover a surface of the epitaxial growth layer 3 from above. The p-side contact electrode 5 is provided to cover the surface of the epitaxial growth layer 3 including the insulating layer 4 from above. The reflecting layer 6 is provided to cover the entire surface of the p-side contact electrode 5. The first protective layer 7 is provided to cover the entire surface of the reflecting layer 6. The second protective layer 8 is provided to cover side surfaces of the epitaxial growth layer 3 and the first protective layer 7. The third protective layer 9 is provided to cover the surface of the first protective layer from above.

Meanwhile, the semiconductor light emitting element 1 of the embodiment has a total reflection suppression layer 10, an n-side contact electrode 11 and a pad electrode 12 on the side of the other surface (an upper surface in FIG. 1) of the substrate 2.

The total reflection suppression layer 10 is provided to cover the other surface of the substrate 2 from above except a contact section 2a of the substrate 2. The n-side contact electrode 11 is provided on the contact section 2a of the substrate 2. The pad electrode 12 is provided on the n-side contact electrode 11.

Further, in the embodiment, for example, while AlGaAs is used in the substrate 2, SiO₂ is used in the insulating layer 4, indium tin oxide (ITO) is used in the p-side contact electrode 5, Ag/Pt is used in the reflecting layer 6, TiW/Pt/Au is used in the first protective layer 7, SiO₂ is used in the second protective layer 8, Ti/Pt/Au is used in the third protective layer 9, TiO₂/SiO₂ is used in the total reflection suppression layer 10, AuGe/Ni is used in the n-side contact electrode 11, and Ti/Au is used in the pad electrode 12, the embodiment is not particularly limited to these materials. In addition, thicknesses of the parts may also be set arbitrarily.

In addition, the semiconductor light emitting element 1 of the embodiment is not particularly limited to the above-mentioned configuration and appropriate modifications may be made without departing from the scope of the present invention.

As shown in FIG. 2, the epitaxial growth layer 3 has a double heterostructure in which at least a first clad layer 21 having a first conductivity type (an n type in the embodiment), the active layer 22 that is a light emitting layer, and a second clad layer 23 having a second conductivity type (a p type in the embodiment) opposite to the first conductivity type are sequentially laminated on the substrate 2.

In addition, the epitaxial growth layer 3 has a configuration in which a first SCH layer 24 having a larger refractive index than that of the first clad layer 21 and a second SCH layer 25 having a larger refractive index than that of the second clad layer 23 are provided on both sides with the active layer 22 sandwiched therebetween in a thickness direction as a separated confinement heterostructure (SCH).

Further, the epitaxial growth layer 3 has a configuration in which, as a current spreading layer (CSL) configured to reduce a spreading resistance of a carrier, a first CSL layer 26 is provided between the first clad layer 21 and the substrate 2 and a second CSL layer 27 is provided between the second clad layer 23 and the p-side contact electrode 5.

Accordingly, the epitaxial growth layer 3 has a structure in which the first CSL layer 26, the first clad layer 21, the first SCH layer 24, the active layer 22, the second SCH layer 25, the second clad layer 23 and the second CSL layer 27 are sequentially laminated through epitaxial growth when seen from the side of the substrate 2. In addition, a p-side contact layer 28 is formed on the second CSL layer 27 through epitaxial growth.

As shown in FIG. 3, the active layer 22 has a quantum well structure configured to enclose an extremely thin quantum well layer 31 having a small band gap with a barrier layer 32 having a large band gap. In addition, the active layer 22 has a multi quantum well (MQW) structure in which pluralities of barrier layers 32 and quantum well layers 31 are alternately laminated in between the barrier layer 32 disposed as the lowermost layer and the barrier layer 32 disposed as the uppermost layer when seen from the side of the substrate 2.

The active layer 22 of the embodiment has, for example, an 11-layered structure in which six barrier layers 32 and five quantum well layers 31 are alternately laminated. Further in FIG. 2 and FIG. 3, for the sake of convenience, only the active layer 22 in which the one quantum well layer 31 is enclosed between the two barrier layers 32 is shown.

Incidentally, the active layer 22 of the embodiment has a first intermediate layer 33A that contains a higher concentration of Al than at least the barrier layer 32 and that is disposed between the quantum well layer 31 and the barrier layer 32 where changing from the quantum well layer 31 to the barrier layer 32, and a second intermediate layer 33B that contains a higher concentration of Al than at least the barrier layer 32 and that is diposed between the barrier layer 32 and the quantum well layer 31 where changing from the barrier layer 32 to the quantum well layer 31, when seen from the side of the substrate 2.

That is, the first intermediate layer 33A is provided between a side of growth completion of the quantum well layer 31 and the barrier layer 32. Meanwhile, the second intermediate layer 33B is provided between a side of growth completion of the barrier layer 32 and the quantum well layer 31. In addition, the first intermediate layer 33A is provided between a surface of the quantum well layer 31 on a side far from the substrate 2 and the barrier layer 32. Meanwhile, the second intermediate layer 33B is provided between a surface of the quantum well layer 31 on a side close to the substrate 2 and the barrier layer 32.

The quantum well layer 31 is constituted by an In-based compound semiconductor that does not contain Al. More specifically, the quantum well layer 31 is constituted by an InGaAs-based compound semiconductor that does not contain Al. The barrier layer 32 is constituted by a GaAsP-based compound semiconductor that does not contain Al. Further, the barrier layer 32 may be formed of a material containing Al, for example, a material such as AlGaAs, AlGaAsP, or the like.

In the active layer 22 of the embodiment, a balance of distortion due to a difference in lattice constant with respect to the substrate 2 can be adjusted by alternately laminating the quantum well layer 31 formed of InGaAs having a larger lattice constant than that of GaAs and the barrier layer 32 formed of GaAsP having a smaller lattice constant than that of GaAs on the substrate 2 formed of GaAs.

Further, “does not contain Al” in the present invention means that completely no Al is contained or Al is substantially not contained in a composition of the compound semiconductor.

The first intermediate layer 33A has a configuration containing a higher concentration of Al than at least the barrier layer 32 on an interface between the quantum well layer 31 and the barrier layer 32. Specifically, the first intermediate layer 33A may be a layer that covers the entire surface of the quantum well layer 31 or may be a layer provided to be distributed in an island form on the surface of the quantum well layer 31. In addition, the first intermediate layer 33A may be a layer containing Al mixed and crystallized between the quantum well layer 31 and the barrier layer 32, or may be a layer in which a concentration of Al is relatively high between the quantum well layer 31 and the barrier layer 32.

Similarly, the second intermediate layer 33B is configured to contain Al in the interface between the barrier layer 32 and the quantum well layer 31. Specifically, the second intermediate layer 33B may be a layer that covers the entire surface of the barrier layer 32, or may be a layer provided to be distributed in an island form on the surface of the barrier layer 32. In addition, the second intermediate layer 33B may be a layer containing Al mixed and crystallized between the barrier layer 32 and the quantum well layer 31, or may be a layer having a relatively high concentration of Al between the barrier layer 32 and the quantum well layer 31.

In the active layer 22 of the embodiment, a thickness of each of the first intermediate layer 33A and the second intermediate layer 33B is preferably 1 nm or more and 3 nm or less, more specifically, 2 monolayers or more and 6 monolayers or less. Accordingly, an increase in forward voltage (Vf) of the semiconductor light emitting element 1 due to an increase in barrier height is minimized.

Meanwhile, when the thickness of each of the first intermediate layer 33A and the second intermediate layer 33B is too thin, an effect may not be sufficiently obtained by providing the first intermediate layer 33A and the second intermediate layer 33B. In addition, a variation easily occurs in a film thickness distribution in the surface. On the contrary, when the thickness of each of the first intermediate layer 33A and the second intermediate layer 33B is too thick, since the layers begin to work as a blocking layer for the carrier, it leads to increase in the above-mentioned Vf.

In addition, the first intermediate layer 33A has a concentration of In higher than that of the second intermediate layer 33B. In the first intermediate layer 33A, it is thought that mixing or diffusion of In into the barrier layer 32 is prevented by taking in In remaining on the surface of the quantum well layer 31 after growth of the quantum well layer 31 constituted by the In-based compound semiconductor.

As described above, in the semiconductor light emitting element 1 of the embodiment, since the change in composition in the interface between the quantum well layer 31 and the barrier layer 32 can be made sharp due to the first intermediate layer 33A and the change in composition in the interface between the barrier layer 32 and the quantum well layer 31 can be made sharp due to the second intermediate layer 33B, an effect of confining the carrier to the quantum well layer 31 can be improved, and luminous efficiency of the semiconductor light emitting element 1 can be further improved.

### Method of Manufacturing Semiconductor Light Emitting Element

Next, a method of manufacturing the semiconductor light emitting element 1 of the embodiment will be described with reference to FIG. 4.

Further, FIG. 4 is a sequence diagram showing a procedure of switching supply of source gases when the active layer 22 is formed.

In the method of manufacturing the semiconductor light emitting element 1 of the embodiment, the epitaxial growth layer 3 is formed by sequentially laminating the first CSL layer 26, the first clad layer 21, the first SCH layer 24, the active layer 22, the second SCH layer 25, the second clad layer 23 and the second CSL layer 27 on the substrate 2 through epitaxial growth using MOCVD.

In addition, the active layer 22 having the quantum well structure in which the quantum well layer 31 is enclosed between the barrier layers 32 is formed while alternately switching between a process of forming the barrier layer 32 through epitaxial growth using a source gas for the barrier layer 32 and a process of forming the quantum well layer 31 through epitaxial growth using a source gas for the quantum well layer 31. Further, in the embodiment, the active layer 22 in which the six barrier layers 32 and the five quantum well layers 31 are alternately laminated is formed.

When the active layer 22 is formed, as shown in FIG. 4, the barrier layer 32 is formed of GaAsP through epitaxial growth using phosphine (PH₃), arsine (AsH₃) and trimethylgallium (TMG) as source gases for the barrier layer 32.

In addition, the quantum well layer 31 is formed of InGaAs through epitaxial growth using arsine (AsH₃), trimethylindium (TMI) and trimethylgallium (TMG) as source gases for the quantum well layer 31.

Further, the first intermediate layer 33A and the second intermediate layer 33B containing Al are formed through epitaxial growth using trimethylaluminum (TMA) as a source gas containing Al.

In the method of manufacturing the semiconductor light emitting element 1 of the embodiment, the first intermediate layer 33A containing Al is formed by crystal growth of Al through epitaxial growth using a source gas (TMA) containing Al between the switching from the process of forming the quantum well layer 31 to the process of forming the barrier layer 32.

In addition, in the method of manufacturing the semiconductor light emitting element 1 of the embodiment, the second intermediate layer 33B containing Al is formed by crystal growth of Al through epitaxial growth using a source gas (TMA) containing Al between the switching from the process of forming the barrier layer 32 to the process of forming the quantum well layer 31.

Here, it is thought that In atoms, Ga atoms, and As atoms before crystallization are attached to the surface of the quantum well layer 31 immediately after the quantum well layer 31 is formed of InGaAs. In particular, it is thought that, since InGaAs has a large lattice constant mismatch with GaAs, the In atoms are not crystallized and unreacted InGaAs remains on the surface of the quantum well layer 31.

After that, when Al atoms are attached to the surface of the quantum well layer 31 due to supply of TMA, since Al is easily crystallized, it is thought that crystallization of the unreacted InGaAs progresses using the Al as an origin. Meanwhile, incorporation of In atoms into the barrier layer 32 formed after that can be prevented. Accordingly, the change in composition in the interface between the quantum well layer 31 and the barrier layer 32 via the first intermediate layer 33A can be made sharp.

Meanwhile, it is thought that In atoms that become the quantum well layer 31 can be easily incorporated thereinto due to attachment of Al atoms to the surface of the quantum well layer 31 due to supply of TMA immediately after the barrier layer 32 is formed of GaAsP. Accordingly, the change in composition in the interface between the barrier layer 32 and the quantum well layer 31 via the second intermediate layer 33B can be made sharp.

As described above, in the method of manufacturing the semiconductor light emitting element 1 of the embodiment, the first intermediate layer 33A containing Al can be formed using the source gas (TMA) containing Al between the switching from the process of forming the quantum well layer 31 to the process of forming the barrier layer 32, and the second intermediate layer 33B containing Al can be formed using the source gas (TMA) containing Al between the switching from the process of forming the barrier layer 32 to the process of forming the quantum well layer 31. Accordingly, it is possible to provide the semiconductor light emitting element 1 in which an effect of confining the carrier to the quantum well layer 31 is improved and luminous efficiency is good.

### Second Embodiment

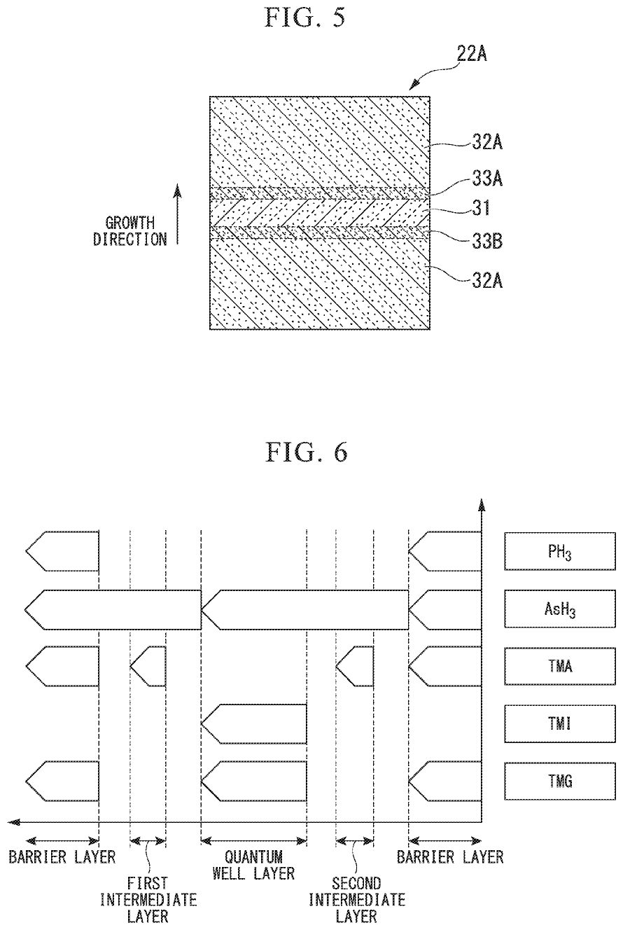

Next, an active layer 22A provided in the semiconductor light emitting element 1 shown in FIG. 5 will be described as a second embodiment of the present invention.

Further, FIG. 5 is a schematic cross-sectional view showing a configuration of the active layer 22A. In addition, in the following description, the same areas as the active layer 22 are designated by the same reference numerals in the drawings and description thereof will be omitted.

The semiconductor light emitting element 1 of the embodiment is configured to include the active layer 22A shown in FIG. 5 instead of the active layer 22 shown in FIG. 3, and have basically the same configuration as the semiconductor light emitting element 1 otherwise.

Specifically, the active layer 22A has basically the same configuration as the active layer 22 except that a barrier layer 32A constituted by an AlGaAsP-based compound semiconductor having a lower concentration of Al than that of a second intermediate layer 33B is provided.

Accordingly, in the active layer 22A, the barrier layer 32A may be constituted by the AlGaAsP-based compound semiconductor. In this case, the second intermediate layer 33B may have a configuration in which a concentration of Al is higher than in the barrier layer 32A.

In the active layer 22A of the embodiment, a balance of distortion due to a difference in lattice constant with respect to the substrate 2 can be adjusted by alternately laminating the quantum well layer 31 formed of InGaAs having a larger lattice constant than that of GaAs and the barrier layer 32A formed of AlGaAsP having a smaller lattice constant than that of GaAs on the substrate 2 formed of GaAs.

In addition, the active layer 22A of the embodiment has a first intermediate layer 33A that contains a higher concentration of Al than at least the barrier layer 32A and that is disposed between the quantum well layer 31 and the barrier layer 32A where changing from the quantum well layer 31 to the barrier layer 32A and a second intermediate layer 33B that contains a higher concentration of Al than at least the barrier layer 32A and that is disposed between the barrier layer 32A and the quantum well layer 31 where changing from the barrier layer 32A to the quantum well layer 31 when seen from the side of the substrate 2.

Accordingly, in the active layer 22A of the embodiment, like the active layer 22, the change in composition in the interface between the quantum well layer 31 and the barrier layer 32A via the first intermediate layer 33A can be made sharp, and the change in composition in the interface between the barrier layer 32A and the quantum well layer 31 via the second intermediate layer 33B can be made sharp. In addition, since the first intermediate layer 33A and the second intermediate layer 33B therebetween have a large band gap, an effect of confining the carrier to the quantum well layer 31 can be increased.

In addition, a procedure of switching supply of source gases when the active layer 22A is formed is shown in FIG. 6.

Further, FIG. 6 is a sequence diagram showing a procedure of switching supply of source gases when the active layer 22A is formed.

When the active layer 22A is formed, as shown in FIG. 6, the barrier layer 32A is formed of AlGaAsP through epitaxial growth using phosphine (PH₃), arsine (AsH₃), trimethylindium (TMI), trimethylgallium (TMG) and trimethylaluminum (TMA) as source gases for the barrier layer 32.

In addition, the quantum well layer 31 is formed of InGaAs through epitaxial growth using arsine (AsH₃), trimethylindium (TMI) and trimethylgallium (TMG) as source gases for the quantum well layer 31.

Further, the first intermediate layer 33A and the second intermediate layer 33B containing Al are formed through epitaxial growth using trimethylaluminum (TMA) as a source gas containing Al.

Accordingly, like the case in which the active layer 22 is formed, the first intermediate layer 33A containing Al using the source gas (TMA) containing Al can be formed between the switching from the process of forming the quantum well layer 31 to the process of forming the barrier layer 32A, and the second intermediate layer 33B containing Al can be formed using the source gas (TMA) containing Al between the switching from the process of forming the barrier layer 32A to the process of forming the quantum well layer 31.

As described above, in the semiconductor light emitting element 1 of the embodiment, since the change in composition in the interface between the quantum well layer 31 and the barrier layer 32A due to the first intermediate layer 33A can be made sharp and the change in composition in the interface between the barrier layer 32A and the quantum well layer 31 due to the second intermediate layer 33B can be made sharp, an effect of confining the carrier to the quantum well layer 31 can be improved, and luminous efficiency of the semiconductor light emitting element 1 can be further improved.

### Third Embodiment

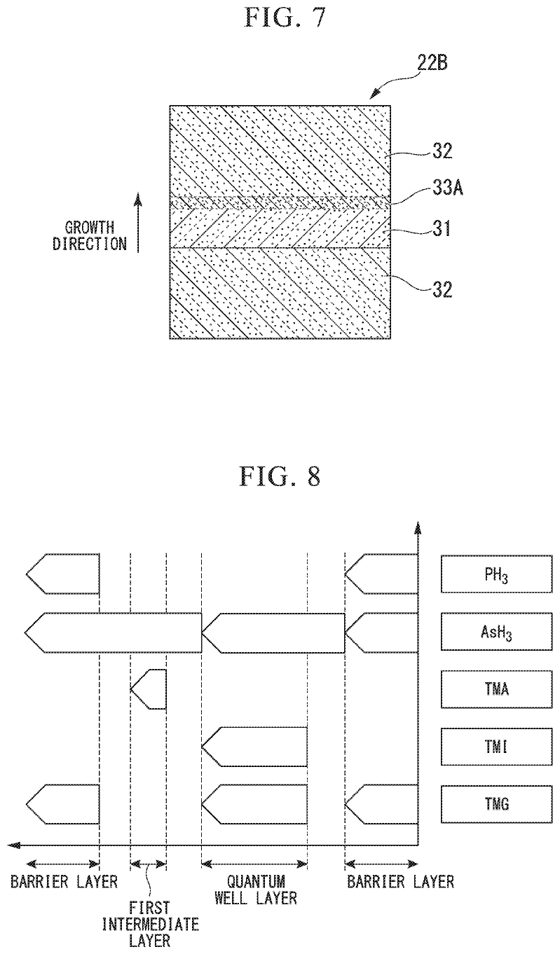

Next, an active layer 22B provided in the semiconductor light emitting element 1 shown in FIG. 7 will be described as a third embodiment of the present invention.

Further, FIG. 7 is a schematic cross-sectional view showing a configuration of the active layer 22B. In addition, in the following description, the same areas as the active layer 22 are designated by the same reference numerals in the drawings and description thereof will be omitted.

The semiconductor light emitting element 1 of the embodiment is configured to include an active layer 22B shown in FIG. 7 instead of the active layer 22 shown in FIG. 3, and has basically the same configuration as in the semiconductor light emitting element 1 except that.

Specifically, the active layer 22B has basically the same configuration as that of the active layer 22 except that the second intermediate layer 33B provided on the active layer 22 is omitted. That is, the active layer 22B that has a configuration in which the first intermediate layer 33A which contains a higher concentration of Al than at least the barrier layer 32 is disposed only between the quantum well layer 31 and the barrier layer 32 where changing from the quantum well layer 31 to the barrier layer 32 when seen from the side of the substrate 2.

Accordingly, in the active layer 22B of the embodiment, the change in composition in the interface between the quantum well layer 31 and the barrier layer 32A via the first intermediate layer 33A can be made sharp. In addition, since the first intermediate layer 33A therebetween has a large band gap, an effect of confining the carrier to the quantum well layer 31 can be increased.

That is, in the active layer 22B of the embodiment, even in the configuration in which the second intermediate layer 33B provided on the active layer 22 is omitted, since the In atoms are prevented from being taken into the barrier layer 32A from the quantum well layer 31 by the first intermediate layer 33A, the change in composition in the interface between the quantum well layer 31 and the barrier layer 32 can be made sharp.

In addition, a procedure of switching supply of source gases when the active layer 22B is formed is shown in FIG. 8.

Further, FIG. 8 is a sequence diagram showing a procedure of switching supply of source gases when the active layer 22B is formed.

When the active layer 22B is formed, as shown in FIG. 6, the barrier layer 32 is formed of AlGaAsP through epitaxial growth using phosphine (PH₃), arsine (AsH₃) and trimethylgallium (TMG) as source gas for the barrier layer 32.

In addition, the quantum well layer 31 is formed of InGaAs through epitaxial growth using arsine (AsH₃), trimethylindium (TMI) and trimethylgallium (TMG) as source gases for the quantum well layer 31.

Further, the first intermediate layer 33A containing Al is formed through epitaxial growth using trimethylaluminum (TMA) as a source gas containing Al.

Accordingly, like the case in which the active layer 22 is formed, the first intermediate layer 33A containing Al can be formed using a source gas (TMA) containing Al between the switching from the process of forming the quantum well layer 31 to the process of forming the barrier layer 32A.

As described above, in the semiconductor light emitting element 1 of the embodiment, since the change in composition in the interface between the quantum well layer 31 and the barrier layer 32A due to the first intermediate layer 33A can be made sharp, an effect of confining the carrier to the quantum well layer 31 can be improved, and luminous efficiency of the semiconductor light emitting element 1 can be further improved.

Further, the present invention is not necessarily limited to the embodiment and various modifications may be made without departing from the scope of the present invention.

For example, in the embodiment, while the case in which the present invention is applied to the LED configured to emit infrared light is exemplified as the semiconductor light emitting element, the present invention may also be applied to a laser diode (LD) configured to emit infrared laser beams. Further, the present invention may also be applied to an LED configured to emit light other than infrared light or an LD configured to emit laser beams other than infrared laser beams.

In addition, as a use of such a semiconductor light emitting element, for example, the light source may also be used in a system configured to recognize a human face image, detect a doze or a looking-away and alarm it as an infrared light source for driver monitoring. In addition, the light source may be used as lighting of a monitoring camera, a security camera, or the like, or nighttime lighting such as night vision or the like. In addition, the light source may be used in a system configured to detect a person or an object when a person or an object enters an intrusion prohibition area, as a light source of an infrared light curtain or the like.

### EXAMPLE

Hereinafter, the effects of the present invention are made clearer by the following examples. Further, the present invention is not limited to the following examples and appropriate modifications may be made without departing from the scope of the present invention.

### Example 1

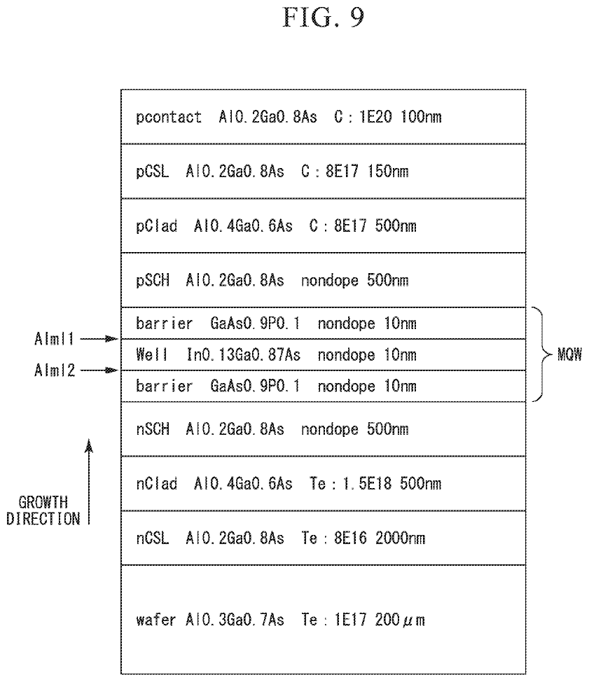

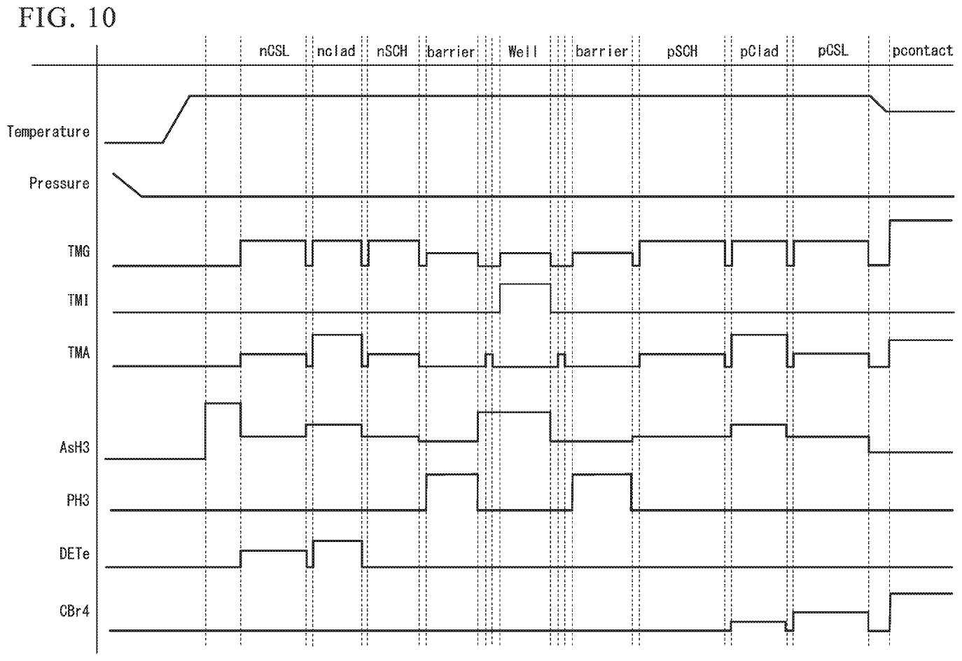

First, a semiconductor light emitting element of Example 1 will be described with reference to FIG. 9 and FIG. 10.

Further, FIG. 9 is a schematic cross-sectional view showing a configuration of a substrate and an epitaxial growth layer provided in the semiconductor light emitting element of Example 1. In addition, FIG. 9 shows compositions and thicknesses [nm] of layers that constitute the substrate and the epitaxial growth layer.

FIG. 10 is a sequence diagram showing a procedure of switching supply of source gases when layers that constitute the epitaxial growth layer are formed. In addition, FIG. 10 shows flow rates [μmol/min] of the source gases supplied when the layers are formed.

In addition, expressions “x×e×n” (n is an integer) in the following description means “x×10ⁿ.”

In Example 1, as shown in FIG. 9, a first CSL layer (nCSL), a first clad layer (nClad), a first SCH layer (nSCH), an active layer (MQW), a second SCH layer (pSCH), a second clad layer (pClad), a second CSL layer (pCSL) and a p-side contact layer (p contact) were sequentially laminated on a substrate (a wafer) through epitaxial growth using MOCVD.

In addition, six barrier layers (barriers) and five quantum well layers (wells) were alternately laminated as the active layer (MQW). Further, in FIG. 9, for the sake of convenience, only the active layer (MQW) in which one quantum well layer (a well) is enclosed between two barrier layers (barriers) is shown.

Specifically, first, a temporary substrate formed of GaAs is prepared. A main surface of the temporary substrate is a (100) surface of GaAs. In addition, the temporary substrate is doped with Si to provide n-type conductivity, and a concentration thereof is about 1e18 atom/cm⁻³.

Next, Al_{0.3}Ga_{0.7}As having a thickness of 250 μm is formed on the main surface of the temporary substrate through crystal growth using liquid phase epitaxy (LPE). Further, an AlGaAs layer thereof is referred to as a support layer.

The LPE is mainly classified as a temperature difference method and a slow cooling method. Here, as described below, the temperature difference method is employed. In addition, in a growth device of the support layer, for example, a slide boat type may be used. In the support layer, Te is doped during growth such that a concentration of Te becomes 1e17 atom/cm⁻³.

A solution for growth uses GaAs, Al and Te dissolved in a Ga solvent. A temperature gradient in an upward/downward direction of the solution for growth filled in a melt tank is about 5° C./cm. A lower section temperature of the solution for growth in contact with a seed crystal is 850 to 950° C. Further, the lower section temperature and the temperature gradient of the solution for growth are substantially constantly held during growth.

Next, the temporary substrate is removed through etching. The temporary substrate is removed through wet etching using etchant obtained by mixing ammonia water and hydrogen peroxide water at a volume ratio of 1:20. Here, the support layer functions as an etching stopper. Accordingly, only the support layer remains.

Next, the surface of the support layer is ground, and roughness of the surface is reduced. Further, after the ground surface is polished to remove processing damage, final finishing by chemical mechanical polishing (CMP) is performed. In general, the layer grown through the temperature difference method has worse flatness on the surface than a layer grown through the slow cooling method. The flatness of the surface can be increased by performing the final finishing through CMP.

The substrate (the wafer) constituted by the above-mentioned support layer (Te-doped Al_{0.3}Ga_{0.7}As) was fabricated through the above-mentioned processes.

Next, as shown in FIG. 10, the epitaxial growth layer is formed on the substrate (the wafer) that is a growth substrate using MOCVD.

Further, AlGaAs having a concentration of Al of 30% is easily oxidized under oxygen atmosphere. That is, when the substrate (the wafer) formed of Al_{0.3}Ga_{0.7}As is exposed to the atmospheric air, the surface is instantly oxidized (natural oxidization). For this reason, after the substrate (the wafer) is immersed in HCl diluted in nitrogen atmosphere and an oxide film on the surface is removed, the substrate is installed in an MOCVD device not to be exposed to the atmospheric air.

Specifically, first, in the MOCVD device, after a growth pressure (pressure) is made to 10 kPa and a growth temperature (temperature) is made to 700° C. while H₂ flows, AsH₃ flows at 8900 μmol/min for five minutes. Further, both of a carrier gas and bubbling gas are H₂ during growth. In addition, in order to remove the natural oxide film on the surface of the substrate (the wafer), heat treatment before growth is performed under reducing atmosphere of AsH₃ for five minutes. Here, the substrate (the wafer) is rotated at 60 rpm.

Next, AsH₃ is made to flow at 2650 μmol/min for 52 minutes as a supply source of a group V element while TMG is made to flow at 45 μmol/min and TMA is made to flow at at 7.95 μmol/min as a supply source of a group III element. In addition, diethyl tellurium (DETe) as impurities showing an n type is made to flow at at 0.04 μmol/min for 52 minutes while replacing the group III element. Accordingly, Te-doped Al_{0.2}Ga_{0.8}As having a thickness of 2000 nm and a concentration of Te of 8e16 atom/cm⁻³ was formed as the first CSL layer (nCSL).

Next, AsH₃ is made to flow at 3130 μmol/min for 13 minutes as a supply source of a group V element while TMG is made to flow at 45 μmol/min and TMA is made to flow at 17.5 μmol/min as a supply source of a group III element. In addition, diethyl tellurium (DETe) as impurities showing an n type flows at 0.052 μmol/min for 13 minutes while replacing the group III element. Accordingly, Te-doped Al_{0.4}Ga_{0.6}As having a thickness of 500 nm and a concentration of Te of 1.5e18 atom/cm⁻³ was formed as the first clad layer (nClad).

Further, an increase in concentration of Al in the first clad layer (nClad) that is higher than that in the first CSL layer (nCSL) and an increase in band gap are in order to make the first clad layer function as the block layer of the carrier.

Next, AsH₃ is made to flow at 2650 μmol/min for 13 minutes as a supply source of a group V element while TMG is made to flow at 45 μmol/min and TMA is made to flow at 7.95 μmol/min as a supply source of a group III element. Accordingly, non-doped Al_{0.2}Ga_{0.8}As having a thickness of 500 nm was formed as the first SCH layer (nSCH).

Next, AsH₃ is made to flow at 2520 μmol/min and PH₃ is made to flow at 7860 μmol/min for 20 seconds as a supply source of a group V element while TMG is made to flow at 26 μmol/min as a supply source of a group III element. Accordingly, non-doped GaAs_{0.9}P_{0.1} having a thickness of 10 nm was formed as the barrier layer (the barrier).

Further, since the quantum well layer (the well) is formed of InGaAs having a larger lattice constant than that of GaAs in the barrier layer (the barrier), the barrier layer was formed of GaAsP having a smaller lattice constant than that of GaAs such that the quantum well layer (the well) has a thickness equal to or larger than a critical film thickness. In addition, the barrier layer (the barrier) was formed of GaAsP having a concentration of P of 10%.

Next, after the barrier layer (the barrier) was formed, supply of TMG and PH₃ is stopped, AsH₃ is instantly changed to 6130 μmol/min and is made to flow for 0.5 seconds, and then, a second intermediate layer (Alml2) containing Al was formed by flowing TMA at 7.4 μmol/min for 0.5 seconds.

Next, supply of TMA is stopped, AsH₃ is made to flow at 6130 μmol/min as a supply source of a group V element, and after 0.5 seconds, TMG is made to flow at 26 μmol/min and TMI is made to flow at 4.9 μmol/min for 20 seconds as a supply source of a group III element. Accordingly, non-doped In_{0.13}Ga_{0.87}As having a thickness of 10 nm was formed as the quantum well layer (the well).

Next, after the quantum well layer (the well) was formed, supply of TMG and TMI is stopped, AsH₃ was instantly changed to 2520 μmol/min and is made to flow for 0.5 seconds, and then, a first intermediate layer (Alml1) containing Al was formed by flowing TMA at 7.4 μmol/min for 0.5 seconds.

Next, supply of TMA is stopped, AsH₃ is made to flow at 2520 μmol/min as a supply source of a group V element, and after 0.5 seconds, TMG is made to flow at 26 μmol/min and PH₃ is made to flow at 7860 μmol/min for 20 seconds as a supply source of a group III element. Accordingly, non-doped GaAs_{0.9}P_{0.1} having a thickness of 10 nm was formed as the barrier layer (the barrier).

Then, as the active layer (MQW), six barrier layers (barriers) and five quantum well layers (wells) were alternately laminated in between the barrier layer (the barrier) disposed as the lowermost layer and the barrier layer (the well) disposed as the uppermost layer while repeating the above-mentioned processes. In addition, the second intermediate layer (Alml2) containing Al was formed between the barrier layer (the barrier) and the quantum well layer (the well), and the first intermediate layer (Alml1) containing Al was formed between the quantum well layer (the well) and the barrier layer (the barrier).

Next, AsH₃ is made to flow at 2650 μmol/min for 13 minutes as a supply source of a group V element while TMG flows at 45 μmol/min and TMA flows at 7.95 μmol/min as a supply source of a group III element. Accordingly, non-doped Al_{0.2}Ga_{0.8}As having a thickness of 500 nm was formed as the second SCH layer (pSCH).

Next, AsH₃ is made to flow at 3130 μmol/min for 13 minutes as a supply source of a group V element while TMG is made to flow at 45 μmol/min and TMA is made to flow at 17.5 μmol/min as a supply source of a group III element. In addition, carbon tetrabromide (CBr₄) as impurities showing a p type is made to flow at 1.48 μmol/min for 13 minutes while replacing the group V element. Accordingly, C-doped Al_{0.4}Ga_{0.6}As having a thickness of 500 nm and a concentration of C of 8e17 atom/cm⁻³ was formed as the second clad layer (pClad).

Next, AsH₃ is made to flow at 2650 μmol/min for 4 minutes as a supply source of a group V element while TMG is made to flow at 45 μmol/min and TMA is made to flow at 7.95 μmol/min as a supply source of a group III element. In addition, carbon tetrabromide (CBr₄) as impurities showing a p type is made to flow at 2.38 μmol/min for 4 minutes while replacing the group V element. Accordingly, C-doped Al_{0.2}Ga_{0.8}As having a thickness of 150 nm and a concentration of C of 8e17 atom/cm⁻³ was formed as the second CSL layer (pCSL).

Next, after a growth temperature (a temperature) is lowered to 550 ° C., AsH₃ is made to flow at 450 μmol/min for 90 seconds as a supply source of a group V element while TMG is made to flow at 85.3 μmol/min and TMA is made to flow at 14.7 μmol/min as a supply source of a group III element. In addition, carbon tetrabromide (CBr₄) as impurities showing a p type is made to flow at 14 μmol/min for 90 seconds while replacing the group V element. Accordingly, C-doped Al_{0.2}Gao_{0.8}As having a thickness of 100 nm and a concentration of C of 1e20 atom/cm⁻³ was formed as the p-side contact layer (a p contact).

Further, since the p-side contact electrode 5 formed of the above-mentioned ITO is formed on the p-side contact layer (the p contact), a high concentration of impurities are required in order to obtain an appropriate contact resistance. For this reason, AsH₃ is lowered to 450 μmol/min, and a concentration of C is made to become 1e20 atom/cm⁻³.

The epitaxial growth layer was formed on the substrate (the wafer) through the above-mentioned processes. In Example 1, the semiconductor light emitting element having the same configuration as that of the semiconductor light emitting element 1 shown in FIG. 1 was fabricated using the substrate (the wafer) on which the epitaxial growth layer is formed.

### Comparative Example 1

In Comparative example 1, the same semiconductor light emitting element as in Example 1 was fabricated, except that the active layer (MQW) is formed while supply of TMA is not performed, between the process of forming the barrier layer (the barrier) and the process of forming the quantum well layer (the well).

That is, in Comparative example 1, the semiconductor light emitting element was fabricated under the same condition as in the semiconductor light emitting element of Example 1 except that the process of forming the first intermediate layer (Alml1) and the second intermediate layer (Alml2) was omitted.

Then, in the semiconductor light emitting element of Example 1 and Comparative example 1, results of measuring an output (W)[mW], a forward voltage (Vf)[V] and an oscillation wavelength (∧p)[nm] are shown in the following table 1.

TABLE 1

| | Output | Vf | Λp |
|---|---|---|---|
| Example 1 | 460 mW | 2.08 V | 935 nm |
| Comparative | 426 mW | 2.02 V | 945 nm |
| Example 1 | | | |

As shown in Table 1, it is confirmed that the semiconductor light emitting element of Example 1 has an output W higher than that of the semiconductor light emitting element of Comparative example 1 and output of about 8% is improved. In addition, it will be appreciated that the semiconductor light emitting element of Example 1 has a forward voltage (Vf) that is minimized to a lower level than that of the semiconductor light emitting element of Comparative example 1. Further, it will be appreciated that the semiconductor light emitting element of Example 1 has an oscillation wavelength (Ap) that is higher than that of the semiconductor light emitting element of Comparative example 1.

### Example 2

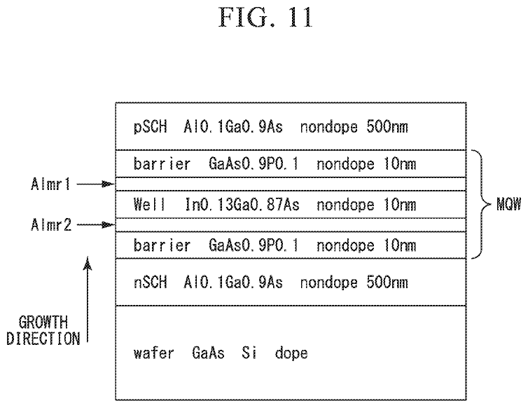

Next, a sample of Example 2 will be described with reference to FIG. 11 to FIG. 15.

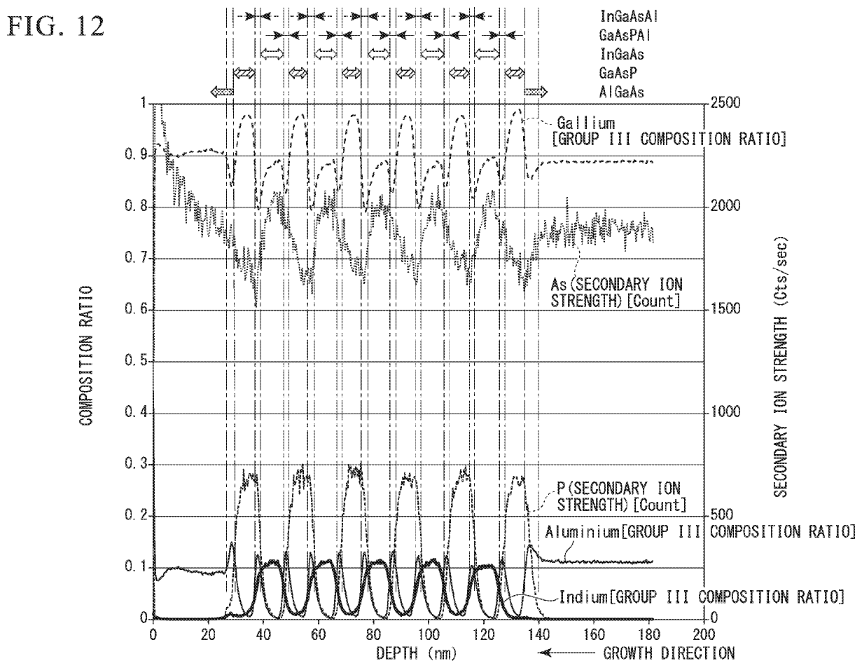

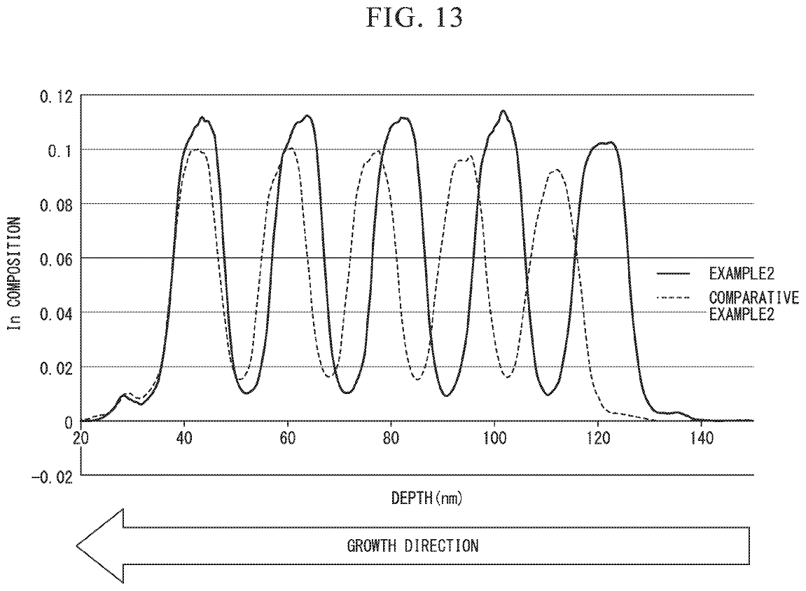

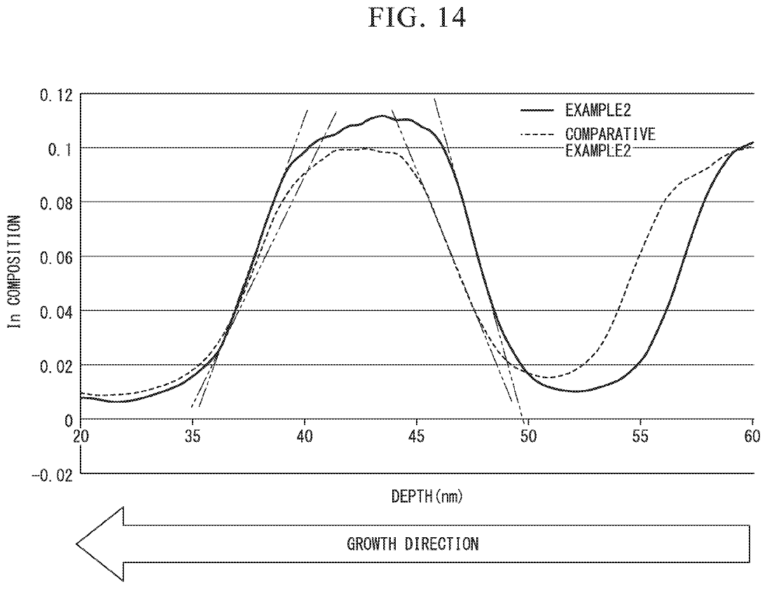

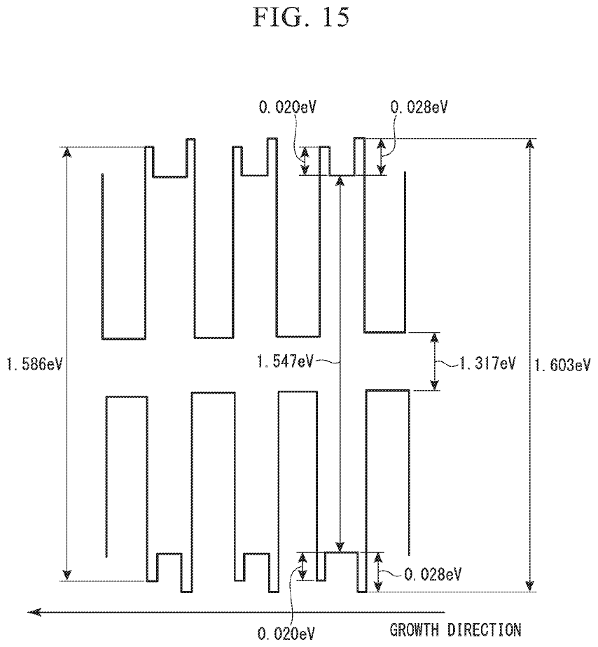

Further, FIG. 11 is a schematic cross-sectional view showing a configuration of the sample. FIG. 12 is a graph showing measurement results by SIMS analysis of the sample. FIG. 13 is a graph showing results of measuring changes in composition of In in samples of Example 2 and Comparative example 2. FIG. 14 is an enlarged graph of a part of the graph shown in FIG. 13. FIG. 15 is a schematic view showing energy levels of layers that constitute the active layer of the sample.

In Example 2, first as shown in FIG. 11, a sample obtained by sequentially laminating the first SCH layer (nSCH), the active layer (MQW) and the second SCH layer (pSCH) on the substrate (the wafer) through epitaxial growth using MOCVD was fabricated as the sample.

In addition, the sample has a composition and a thickness [nm] shown in FIG. 11. That is, the sample has the same active layer (MQW) as in Example 1 except that a composition of the first SCH layer (nSCH) and the second SCH layer (pSCH) is “non-doped Al_{0.1}Ga_{0.9}As,” and the sample was fabricated under the same condition as in Example 1.

Accordingly, in the active layer (MQW) of Example 2, the six barrier layers (barriers) and the five quantum well layers (wells) are alternately laminated, the first intermediate layer (Alml1) containing Al is provided between the quantum well layer (the well) and the barrier layer (the barrier) and the second intermediate layer (Alml2) containing Al is provided between the barrier layer (the barrier) and the quantum well layer (the well).

Next, measurement results by SIMS analysis of the active layer (MQW) of the obtained sample are shown in FIG. 12. Further, in the measurement, a composition ratio by quantitative measurement was obtained using “In_{0.53}Ga_{0.47}As” and “Al_{0.31}Ga_{0.69}As” as a standard sample.

In Example 2, as shown in FIG. 12, vertical lines are drawn with reference to a composition ratio of Al of 0.1, and compositions of the layers were reviewed.

From the measurement results shown in FIG. 12, it was confirmed that, after the barrier layer (the barrier) is formed of GaAs_{0.8}P_{0.1}, the second intermediate layer (Alml2) containing Al is formed due to supply of TMA, and after the quantum well layer (the well) is formed of In_{0.13}Ga_{0.87}S, the first intermediate layer (Alml1) containing Al is formed due to supply of TMA.

Among these, as considering together with a additional SIMS analysis result for obtaining the composition ratios of P and As, it is thought that the first intermediate layer (Alml1) is formed of (Al_{0.12}Ga_{0.81}In_{0.07}As)_{0.91}P_{0.09} having a thickness of 2 nm and formed by mixed crystals of Al, Ga, In, As and P. The first intermediate layer (Alml1) has a higher concentration of In than that in the second intermediate layer (Alml2), and the concentration of In is decreased from the side of the quantum well layer (the well) toward the barrier layer (the barrier).

Accordingly, it is thought that about 7% of In atoms that are not taken into the quantum well layer (the well) are taken into the first intermediate layer (Alml1) by Al after crystal growth of the quantum well layer (the well). In addition, it is thought that the first intermediate layer (Alml1) has a function of preventing the taking in In atoms into the barrier layer (barrier) which will be crystal growth later on and preventing preventing the In atoms from being diffused, by taking the In atoms thereinto.

Meanwhile, as considering together with a additional SIMS analysis result for obtaining the composition ratios of P and As, it is thought that the second intermediate layer (Alml2) is formed of (Al_{0.12}Ga_{0.85}In_{0.03}As)_{0.96}P_{0.04} having a thickness of 2 nm and formed by mixed crystals of Al, Ga, In, As, P. The second intermediate layer (Alml2) has a lower concentration of In than that in the first intermediate layer, and the concentration of In is decreased from the side of the quantum well layer (the well) toward the barrier layer (the barrier).

Accordingly, since the In atoms are supplied after the Al atoms are supplied in the second intermediate layer (Alml2), while taking-in of the In atoms is not seen as in the first intermediate layer (Alml1), taking-in of about 3% of In was seen. In addition, it is thought that the second intermediate layer (Alml2) has a function of preventing diffusion of the In atoms from the quantum well layer (the well) to the barrier layer (the barrier) which will be crystal growth later.

Further, the concentration of P in the second intermediate layer (Alml2) is extremely low, and lower than the concentration of P in the first intermediate layer.

In addition, in the first intermediate layer (Alml1) and the second intermediate layer (Alml2), an increase in concentration of Al corresponds to a decrease in concentration of Ga.

In addition, in either the first intermediate layer (Alml1) and the second intermediate layer (Alml2), the concentration of Al is larger than the concentration of In.

In addition, as a result of secondary ion strength, an increase and a decrease in each of As and P were confirmed.

In addition, while the layers having a composition ratio of Al of 0.1 or more can be identified on both sides of the quantum well structure, the layers are formed unintentionally when supply of TMA is switched and considered as parts of the first SCH layer (nSCH) and the second SCH layer (pSCH).

Next, in the sample of Example 2, the results obtained by measuring the changes in composition of In in the active layer (MQW) through SIMS analysis are shown by solid lines in FIG. 13 and FIG. 14.

### Comparative Example 2

In addition, as Comparative example 2, a sample in which an active layer (MQW) formed without performing supply of TMA between the process of forming the barrier layer (the barrier) and the process of forming the quantum well layer (the well) was fabricated. Here, in the sample of Comparative example 2, the results obtained by measuring the changes in composition of In in the active layer (MQW) through SIMS analysis are shown by broken lines in FIG. 13 and FIG. 14.

As shown in FIG. 13 and FIG. 14, in the sample of Example 2, it will be appreciated that the change in composition of In in the interface between the quantum well layer (the well) and the barrier layer (the barrier) is sharp in comparison with the sample of Comparative example 2. In addition, it is thought that mixing or diffusion of In in the barrier layer (the barrier) can be minimized by the first intermediate layer (Alml1) and the second intermediate layer (Alml2), and the quantum well layer (the well) having a composition containing a predetermined amount of In can be formed. Accordingly, in the sample of Example 2, high output can be obtained by increasing an effect of confining the carrier to the quantum well layer (the well) in comparison with the sample of Comparative example 2.

Next, in the sample of Example 2, FIG. 15 shows energy levels estimated for layers that constitute the active layer (MQW).

A band gap of the quantum well layer (the well) of In_{0.13}Ga_{0.87}As was estimated as 1.317 eV, and a band gap of the barrier layer (the barrier) of GaAs_{0.9}P_{0.1} was estimated as 1.547 eV.

A band gap of the first intermediate layer (Alml1) of (Al_{0.12}Ga_{0.81}In_{0.07}As)_{0.91}P_{0.09} can be estimated as 1.603 eV, and a band gap of the second intermediate layer (Alml2) of (Al_{0.12}Ga_{0.85}In_{0.03}As)_{0.96}P_{0.04} can be estimated as 1.586 eV.

Hereinafter, a method of calculating a band gap will be described.

First, a band gap of GaAs is 1.424 eV. A band gap of AlAs is 2.168 eV. A band gap of InAs is 0.354 eV. A band gap of GaP is 2.26 eV.

Here, in the GaAs—AlAs mixed crystal system, since the case in which the composition of Al is less than 0.45 is a direct transition type and the case in which the composition of Al is 0.45 or more is an indirect transition type, in the drawings showing relations between the band gaps and the composition ratios, the composition of Al has an inflection point in the vicinity of 0.45. In addition, either the first intermediate layer (Alml1) or the second intermediate layer (Alml2) has the composition of Al that is less than 0.45.

Here, in calculation of the band gap of the first intermediate layer (Alml1) and the second intermediate layer (Alml2), 2.671 eV, which is a case when the composition of Al is 1.0 according to a straight line approximating the band gap of the direct transition region in which the composition of Al is less than 0.45, is used as the band gap of AlAs.

In addition, even in the InAs—GaP mixed crystal system, since the case in which the composition of P is less than 0.45 is a direct transition type and the case in which the composition of P is 0.45 or more is an indirect transition type, in the drawings showing the relations between the band gaps and the composition ratios, an inflection point is provided when the composition of P is in the vicinity of 0.45. In addition, any one of the barrier layer (barrier), the first intermediate layer (Alml1) and the second intermediate layer (Alml2) has the composition of P that is less than 0.45.

Here, in calculation of the band gaps of the barrier layer (barrier), the first intermediate layer (Alml1) and the second intermediate layer (Alml2), 2.6529 eV, which is a case when the composition of P is 1.0 according to a straight line approximating the band gap of the direct transition region in which the composition of P is less than 0.45, is used as a band gap of GaP.

That is, the following calculation was performed provided that a band gap (Eg_{(GaAs)}) of GaAs is 1.424 eV, a band gap (Eg_{(AlAs)}) of AlAs is 2.671 eV, a band gap (Eg_{(InAs)}) of InAs is 0.354 eV, and a band gap (Eg_{(GaP)}) of GaP is 2.6529 eV.

Since the first intermediate layer (Alml1) is (Al_{0.12}Ga_{0.81}In_{0.07}As)_{0.91}P_{0.09}, a band gap (Eg1) of the first intermediate layer (Alml1) can be obtained by the follow equation (1).

Eg1=(0.12×Eg_{(AlAs)}+0.81×Eg_{(GaAs)}+0.07×Eg_{(InAs)})×0.91+0.09×Eg_{(GaP)}

Eg1=(0.32051+1.15344+0.02478)×0.91+0.238761=1.602614 (1)

Since the second intermediate layer (Alml2) is (Al_{0.12}Ga_{0.85}In_{0.03}As)_{0.96}P_{0.04}, a band gap (Eg2) of the second intermediate layer (Alml2) can be obtained by the following equation (2).

Eg2=(0.12×Eg_{(AlAs)}+0.85×Eg_{(GaAs)}+0.03×Eg_{(InAs)})×0.96+0.04×Eg_{(GaP)}

Eg2=(0.32051+1.12104+0.01062)×0.96+0.106116=1.585994 (2)

That is, the first intermediate layer (Alml1) and the second intermediate layer (Alml2) have a band gap that is larger than that of the barrier layer (the barrier). Accordingly, it is thought that, since fluctuation of the band gap of the quantum well layer (the well) can be minimized, an effect of confining the carrier to the quantum well layer (the well) can be maintained.

While preferred embodiments of the invention have been described and illustrated above, it should be understood that these are exemplary of the invention and are not to be considered as limiting. Additions, omissions, substitutions, and other modifications can be made without departing from the scope of the present invention. Accordingly, the invention is not to be considered as being limited by the foregoing description, and is only limited by the scope of the appended claims.

What is claimed is:

1. A semiconductor light emitting element comprising a structure in which a first clad layer having a first conductivity type, an active layer in which a quantum well layer is enclosed between barrier layers, and a second clad layer having a second conductivity type opposite to the first conductivity type are sequentially laminated on at least a substrate,
wherein the quantum well layer is constituted by an In-based compound semiconductor that does not contain Al, and
the active layer contains a higher concentration of Al than at least the barrier layer in an interface between the quantum well layer and the barrier layer where changing from the quantum well layer to the barrier layer when seen from a side of the substrate.

2. The semiconductor light emitting element according to claim 1, wherein the quantum well layer is constituted by an InGaAs-based compound semiconductor that does not contain Al.

3. The semiconductor light emitting element according to claim 1, wherein the active layer contains a higher concentration of Al than at least the barrier layer in the interface between the barrier layer and the quantum well layer where changing from the barrier layer to the quantum well layer when seen from the side of the substrate.

4. The semiconductor light emitting element according to claim 3, wherein the barrier layer is constituted by a GaAsP-based compound semiconductor that does not contain Al, or an AlGaAsP-based compound semiconductor having a lower concentration of Al than in the interface between the barrier layer and the quantum well layer.

5. The semiconductor light emitting element according to claim 3, wherein, when seen from the side of the substrate, the active layer has a first intermediate layer that contains a higher concentration of Al than at least the barrier layer and that is disposed between the quantum well layer and the barrier layer where changing from the quantum well layer to the barrier layer, and a second intermediate layer that contains a higher concentration of Al than at least the barrier layer and that is disposed between the barrier layer and the quantum well layer where changing from the barrier layer to the quantum well layer, and
the first intermediate layer has a higher concentration of In than the second intermediate layer.

6. The semiconductor light emitting element according to claim 1, wherein, when seen from the side of the substrate, the active layer has a multi quantum well structure in which the barrier layer and the quantum well layer are alternately laminated in between the barrier layer disposed as the lowermost layer and the barrier layer disposed as the uppermost layer.

7. A method of manufacturing a semiconductor light emitting element comprising a structure in which a first clad layer having a first conductivity type, an active layer in which a quantum well layer is enclosed between barrier layers, and a second clad layer having a second conductivity type opposite to the first conductivity type are sequentially laminated on at least a substrate,
the method comprising:
forming the active layer in which the quantum well layer is enclosed between the barrier layers while alternately switching between a process of forming the barrier layer through epitaxial growth using a source gas for the barrier layer and a process of forming the quantum well layer through epitaxial growth using a source gas for the quantum well layer,
performing crystal growth of an In-based compound semiconductor that does not contain Al in the process of forming the quantum well layer; and
performing crystal growth of Al through epitaxial growth using a source gas containing Al between the switching from the process of forming the quantum well layer to the process of forming the barrier layer.

8. The method of manufacturing the semiconductor light emitting element according to claim 7, wherein crystal growth of an InGaAs-based compound semiconductor that does not contain Al is performed in the process of forming the quantum well layer.

9. The method of manufacturing the semiconductor light emitting element according to claim 7, wherein crystal growth of Al is performed through epitaxial growth using a source gas containing Al between the switching from the process of forming the barrier layer to the process of forming the quantum well layer.

10. The method of manufacturing the semiconductor light emitting element according to claim 9, wherein crystal growth of a GaAsP-based compound semiconductor that does not contain Al or an AlGaAsP-based compound semiconductor having a lower concentration of Al than that in an interface between the barrier layer and the quantum well layer is performed in the process of forming the barrier layer.

11. The method of manufacturing the semiconductor light emitting element according to claim 7, wherein trimethylaluminum (TMA) is used as the source gas containing Al.

12. The method of manufacturing the semiconductor light emitting element according to claim 7, wherein, when seen from a side of the substrate, the active layer that has a multi quantum well structure in which pluralities of the barrier layers and the quantum well layers are alternately laminated in between the barrier layer disposed as the lowermost layer and the barrier layer disposed as the uppermost layer is formed.
